(19) United States
(12) Patent Application Publication
(10) Pub. No.: US 2009/0008792 A1
(43) Pub. Date: Jan. 8, 2009

(54) Three-dimensional chip-stack package and active component on a substrate

(75) Inventors: Cheng-Ta Ko, Chu-Tung (TW); Su Tsai Lu, Chu-Tung (TW)

Correspondence Address: HARNESS, DICKEY & PIERCE, P.L.C., P.O. BOX 8910, RESTON, VA, 20195, US

(73) Assignee: INDUSTRIAL TECHNOLOGY RESEARCH INSTITUTE

(21) Appl. No.: 12/232,019

(22) Filed: Sep. 10, 2008

Related U.S. Application Data
(63) Continuation-in-part of application No. 11/252,572, filed on Oct. 19, 2005.

(30) Foreign Application Priority Data
Nov. 19, 2004 (TW) 93135743

(51) Int. Cl. H01L 23/538; H05K 7/20

(52) U.S. Cl. 257/774; 361/718; 257/E23.174

(57) ABSTRACT

The 3D chip-stack package comprises a component-embedded plate and a side IC. The PCB has a plurality of conductive contacts. The component-embedded plate comprises a dielectric layer; an active component embedded in the dielectric layer, one surface of each active component exposed outside the dielectric layer, the active components having a plurality of TSVs (Through Silicon Via), one ends of the TSVs exposed outside the exposed surface, the other ends of the TSVs corresponding to the conductive contacts of the PCB; and an electrical circuit on the dielectric layer and in electrical connection between the other ends of the TSVs of the active component and the corresponding conductive contacts of the PCB, respectively. The side IC has a plurality of pads. The pads are electrically connected with the exposed ends of the TSVs of the active component.

The present application is a continuation-in-part of parent application Ser. No. 11/252,572, filed Oct. 19, 2005, which claims the benefit of Taiwan Patent Application No. 093135743, filed on Nov. 19, 2004. The parent application and the Taiwan application are hereby incorporated by reference for all purposes as if fully set forth herein.

### BACKGROUND

1. Field of Invention

The invention relates to a three-dimensional (3D) chip-stack package structure. In particular, it relates to a structure of embedded active components having TSVs (through silicon via).

2. Related Art

In order to create larger space and to enhance the functions of the module within a limited substrate area, shrunk or embedded passive components are often used to minimize the circuit layout and to reduce the signal transmission distance. Thus, more space is left for installing active components and enhancing the overall performance. Therefore, substrates with passive components such as embedded resistors, capacitors, and inductors are developed.

In order to more effectively minimize the packaging of the components, methods of embedding active components (such as IC chips) on a substrate have been developed. The substrate with an embedded IC module as disclosed in the U.S. Pat. No. 5,497,033 has a plurality of chips installed thereon. A molding plate is first used to enclose the chips to be the embedded components. A molding material then covers the chips using the conventional molding method. The chips are thus embedded in the molding material after curing. However, this method completes the whole process of embedding components on the substrate. It is likely to damage other components not to be embedded. The finished substrate is not flexible and has limited applications.

In the U.S. Pat. No. 6,027,958, a transferring manufacturing method for the flexible IC components is taught. A semiconductor substrate with silicon on insulator (SOI) structure is provided to form the required IC thereon. An adhesive layer is used to attach another flexible substrate on the IC. Finally, etching is employed to remove the semiconductor substrate, thereby transferring the IC onto the surface of the flexible substrate.

In US Patent Publication No. 2007/0222050 (hereafter called as Pub. '050), a stack package utilizing through vias and re-distribution lines, introduces a stack package. The stack package includes a printed circuit board (PCB), at least two semiconductor chips stacked on the PCB, first and second solder balls, a molding material, and third solder balls. Each of the chips has first re-distribution lines formed on the upper surface thereof and connected to bonding pads, TSVs (through silicon vias) formed therethrough and connected to the first re-distribution lines, and second re-distribution lines formed on the lower surface thereof and connected the TSVs. The first and second solder balls interposed between the first and second re-distribution lines which face each other and between the first re-distribution lines of the lowermost semiconductor chip and electrode terminals of the PCB. The molding material is for molding the upper surface of the PCB. The third balls attach to ball lands formed on the lower surface of the PCB.

As described above, the Pub. '050 discloses a re-distribution structure of 3D chip-stack package to gain more space and better distribution of bonding pads. Although Pub. '050 re-distributes the bonding pads by several stacked ICs, the bonding strength is not good enough. The reason is that the materials between the semiconductor chip and PCB are different. C_{T} (coefficient of thermo expansion) is thus different. In other words, C_{T} of the chip mismatches that of the PCB. Accordingly, thermo stress is incurred at the solder balls between the chip and the PCB when ambient temperature changes. This will cause cracks and bad electrical connections.

Hence, re-distribution (fan-out) of bonding pads of stacked ICs as well as less thermo stress between the PCB and stacked IC are eager to be reached in the IC package field.

### SUMMARY OF THE INVENTION

In view of the foregoing, an objective of the invention is to provide 3D chip-stack package adapted to be disposed on a PCB with less thermo stress therebetween. The thermo stress problem in subsequence can be solved.

The 3D chip-stack package comprises a component-embedded plate and a side IC (integrated circuit). The PCB has a plurality of conductive contacts. The component-embedded plate comprises a dielectric layer; an active an active component embedded in the dielectric layer, one surface of each active component exposed outside the dielectric layer, the active components having a plurality of TSVs (Through Silicon Via), one ends of the TSVs exposed outside the exposed surface, the other ends of the TSVs corresponding to the conductive contacts of the PCB; and an electrical circuit on the dielectric layer and in electrical connection between the other ends of the TSVs of the active component and the corresponding conductive contacts of the PCB, respectively. The side IC has a plurality of pads. The pads are electrically connected with the exposed ends of the TSVs of the active component.

The pitches between the TSVs of the active component are smaller than the pitches between the conductive contacts of the PCB. Therefore, the 3D chip-stack package achieves the results of re-distribution (fan-out) of bonding pads of stacked ICs and less thermo stress between the PCB and stacked IC.

Another objective of the invention is to provide a structure of active component on a flexible substrate.

The structure of active component on a flexible substrate comprises a component-embedded plate and a flexible substrate. The component-embedded plate comprises a dielectric layer, an active component, and an electrical circuit. The dielectric layer has a first surface, a second surface and a plurality of conductive holes. The conductive holes penetrate the dielectric layer and are connected between the first surface and the second surface. The active component is embedded in the dielectric layer. One surface of active component exposed outside the first surface of the dielectric layer. The active component has a plurality of TSVs (Through Silicon Via). One ends of the TSVs are exposed outside the exposed surface of the active component. The other ends of the TSVs are connected with a part of the conductive holes. The electrical circuit is on the dielectric layer and in electrical connection between the other ends of the TSVs of the active component and the other part of the conductive holes through the part of the conductive holes The flexible substrate has a plurality of conductive contacts corresponding to and electrically connected with both the exposed ends of the TSVs and the other part of the through holes.

### BRIEF DESCRIPTION OF THE DRAWINGS

The invention will become more fully understood from the detailed description given hereinbelow illustration only, and thus are not limitative of the present invention, and wherein:

FIG. 1 is a schematic view of the disclosed method;

FIGS. 2A to 2F are schematic cross-sectional views of the manufacturing process according to an embodiment of the invention;

FIG. 3 is a schematic cross-sectional view of another embodiment of the invention;

FIG. 4 is a schematic cross-sectional view of an embodiment of a 3D chip-stack package according to the invention;

FIG. 5 is a schematic perspective view of FIG. 4;

FIG. 6 is a schematic cross-sectional view of another embodiment of a 3D chip-stack package according to the invention;

FIG. 7 is a schematic cross-sectional view of a first embodiment of active component on a substrate according to the invention;

FIG. 8 is a schematic cross-sectional view of a second embodiment of active component on a substrate according to the invention;

FIG. 9 is a schematic cross-sectional view of a third embodiment of active component on a substrate according to the invention;

FIG. 10 is a schematic cross-sectional view of a fourth embodiment of active component on a substrate according to the invention; and

FIG. 11 is a schematic cross-sectional view of a fifth embodiment of active component on a substrate according to the invention.

### DETAILED DESCRIPTION

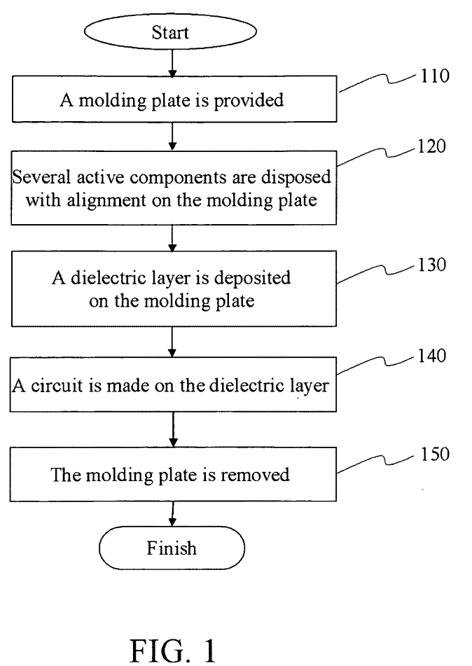

The steps of the disclosed method are shown in FIG. 1. First, a molding plate is provided (step 110). Several active components are disposed with alignment on the molding plate (step 120). A dielectric layer is deposited on the molding plate (step 130) to cover the active components. A circuit is made on the dielectric layer (step 140), in contact with the active components. Finally, the molding plate is removed (step 150), releasing the dielectric layer with embedded active components from the molding plate. One then obtains a structure of embedded active components.

When the dielectric layer is a polymer layer, it can be a preprocessed or existing polymer layer, such as the Ajinomoto build-up film (ABF) or the resin coated copper foil (RCC). The above process also includes the step of embossing to embed active components into the polymer layer or the step of coating a polymer solution followed by curing to form the dielectric layer. The latter includes the steps of: covering a polymer solution on the active components by spraying, spin-coating, or printing; and curing the polymer solution to form a polymer layer.

Step 140 in FIG. 1 makes a circuit on the insulator. Several conductive holes connecting to the active components are first formed on the dielectric layer, followed by forming the circuit passing through the conductive holes.

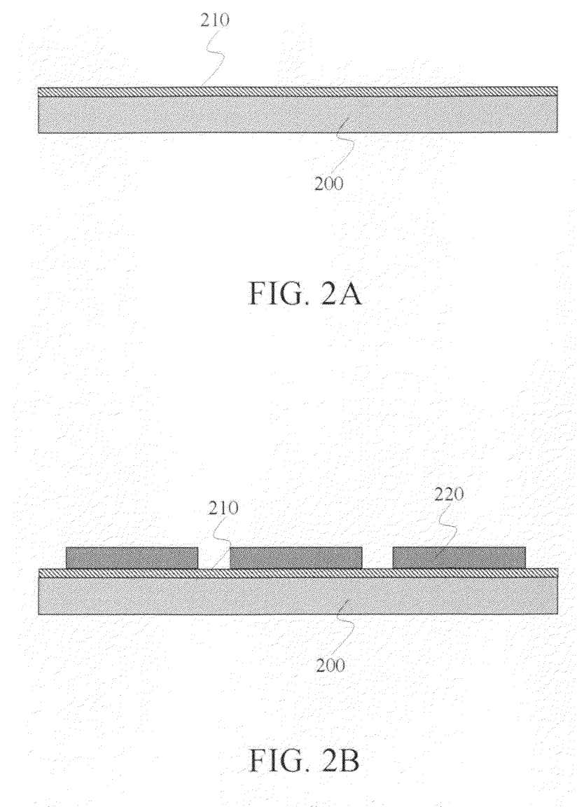

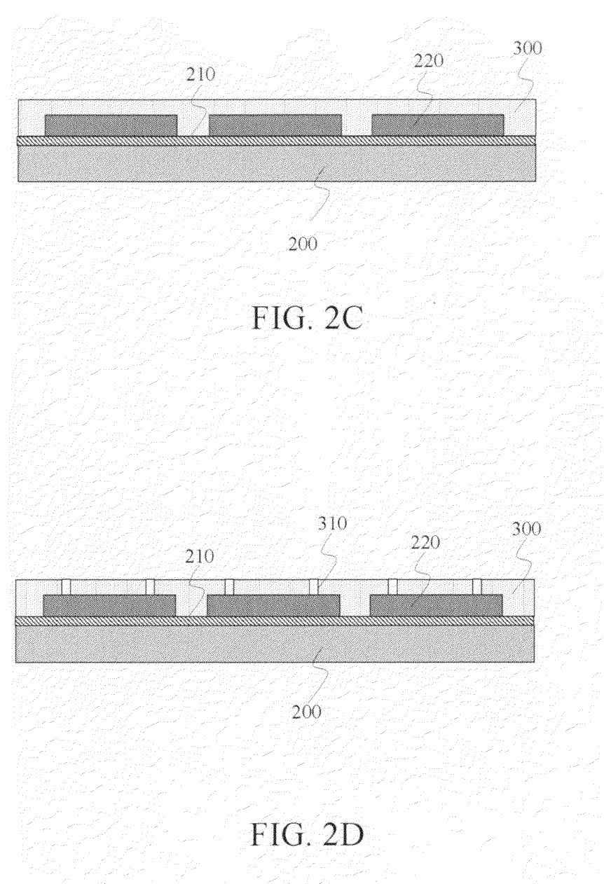

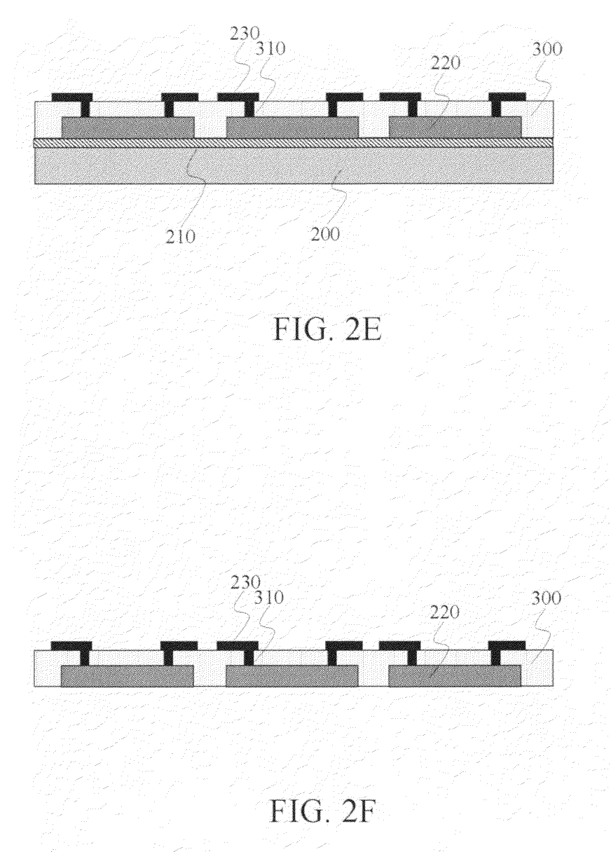

The process in an embodiment of the invention is further described in detail with reference to FIGS. 2A to 2F.

As shown in FIG. 2A, a metal mold-departing layer 210 is deposited on a molding plate 200. The molding material can be Teflon that can be readily removed from the molding plate. The mold-departing layer can be made of any other material with a similar property.

As shown in FIG. 2B, the active components 220 are disposed with alignment on the molding plate 200.

As shown in FIG. 2C, a polymer layer 300 is coated on the molding plate 200 as a dielectric layer to cover the active components. The polymer layer is cured according to the properties of the selected polymer.

As shown in FIG. 2D, several conductive holes 310 connecting to the active components 220 are formed on the polymer layer 300. The conductive holes 310 can be formed using laser, etching, or direct exposure. The conductive holes 310 are further processed by desmearing.

As shown in FIG. 2E, a metal layer 230 is deposited on the polymer layer 300. Photolithography is employed to transfer the required pattern onto the metal layer 230, forming the circuit with the conductive holes thereon.

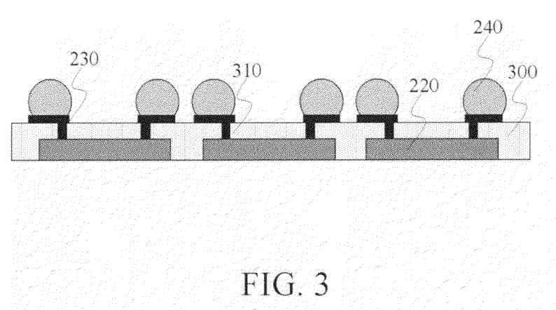

Finally, as shown in FIG. 2F, the molding plate is released from the polymer layer 300 embedded with active components 220 to form a structure of embedded active components. After the molding plate is released, one surface of each embedded active component is exposed outside the dielectric layer as shown in FIG. 2F and FIG. 3.

The structure of embedded active components formed using the process of the disclosed embodiment is shown in FIG. 2F to contain the polymer layer 300, the active components 220, and the circuit. The active components 220 are embedded in the polymer layer 300 and one surface of each embedded active component 220 is exposed outside the dielectric layer as shown in FIG. 2F and FIG. 3. The circuit is formed on the polymer layer 300 and connected to the active components 220 via the conductive holes.

FIG. 3 shows a cross-sectional view of another embodiment of the invention. The above-mentioned structure of embedded active components can be implanted with soldering balls 240 at the contact points of the circuit for subsequent electrical connections.

The disclosed structure of embedded active components can be installed with an arbitrary substrate, such as the semiconductor substrate, flexible substrate, or glass substrate. Since the active components have fixed relative positions, only one alignment is required to fix the positions of all the active components. This can greatly lower the difficulty in subsequent processes and increase the product yield.

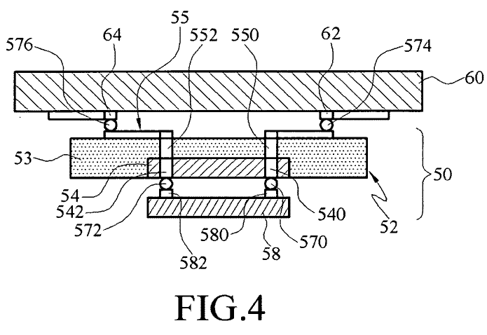

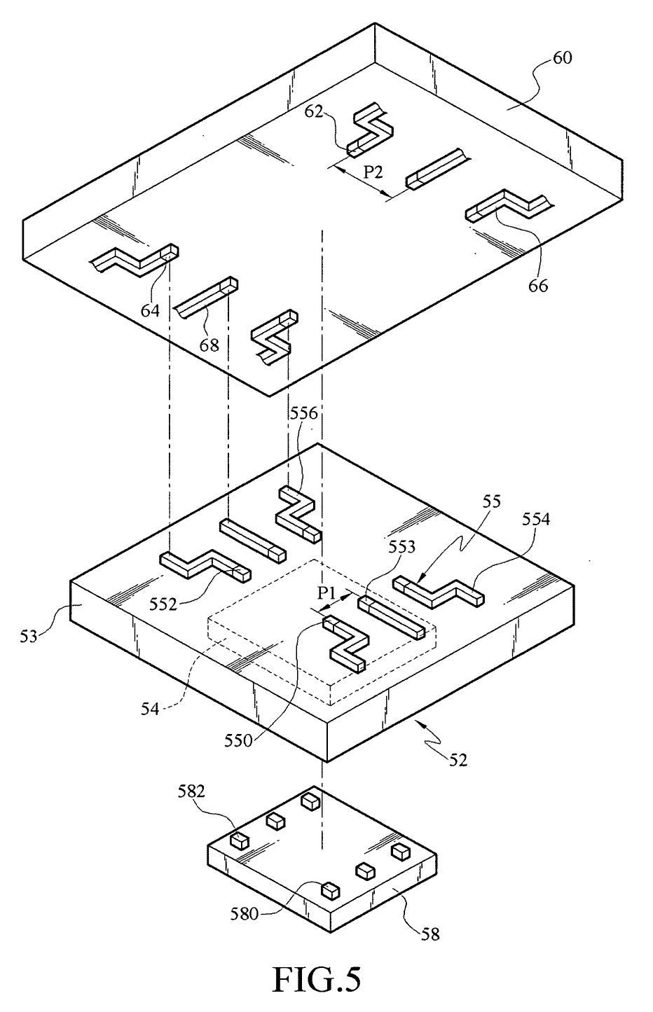

Please refer to FIG. 4 and FIG. 5 simultaneously. FIG. 4 is a schematic cross-sectional view of an embodiment of a 3D chip-stack package according to the invention. FIG. 5 is a schematic perspective view of FIG. 4.

The three-dimensional (hereafter called as 3D) chip-stack package 50 is adapted to be disposed on a printed circuit board 60 (hereafter called as PCB). The PCB 60 has a plurality of conductive contacts 62, 64 and a plurality of circuits 66, 68. The circuits 66, 68 are connected to the conductive contacts 62, 64 for specific functions, respectively. The circuits 66, 68 can comprise a plurality of conductive through holes (not shown in drawings).

The 3D chip-stack package 50 comprises a component-embedded plate 52 and a side integrated circuit 58 (hereafter called as IC).

The component-embedded plate 52 comprises a dielectric layer 53, an active component 54 and an electrical circuit 55. The dielectric layer 53 is similar to the polymer layer 300 in FIG. 3 and is a polymer layer.

The active component 54 is embedded in the dielectric layer 53 and one surface of active component 54 is exposed outside the dielectric layer 53. The active component 54 has a plurality of TSVs (Through Silicon Via) 540, 542. One ends of the TSVs 540, 542 (the bottom ends of TSVs shown in FIG. 4) are exposed outside the exposed surface. The other ends of the TSVs 540, 542 (the top ends of TSVs shown in FIG. 4) correspond to the conductive contacts 62, 64 of the PCB 60, respectively.

The TSVs 540, 542 are vertical electrical connection passing completely through the active component 54, just like a conductive through holes on a PCB 60.

The electrical circuit 55 is on the dielectric layer 53 and in electrical connection between the other ends of the TSVs 540, 542 of the active component 54 and the corresponding conductive contacts 62, 64 of the PCB 60, respectively. As shown in FIG. 5, the electrical circuit 55 includes conductive through holes 550, 552 (filled in holes of the dielectric layer 53) and re-distribution lines 554, 556. The conductive through holes 550, 552 correspond to and are electrically connected with the TSVs 540, 542. Hence, the pitches between conductive through holes 550, 552 are substantially the same as the pitches between the TSVs 540, 542. The re-distribution lines 554, 556 make the TSVs 540, 542 fanned out and electrically connected with corresponding conductive contacts 62, 64 of the PCB 60, respectively. Accordingly, referring to FIG. 5, the pitch P1 of between the conductive through holes 550, 553 are smaller than the pitch P2 between the conductive contacts 62, 64 of the PCB 60. The pitches between the TSVs 540, 542 of the active component 54 are thus smaller than the pitches between the conductive contacts 62, 64 of the PCB 60.

The side IC 58 has a plurality of conductive pads 580, 582. The pads 580, 582 are electrically connected with the exposed ends of the TSVs 540, 542 of the active component 54 to form a 3D chip-stack package.

The active component 54 and the side IC 58 have integrated electrical circuits inside for performing specific functions. In addition, the side IC 58 can be a regular IC or an IC with TSVs.

Please refer to FIG. 4 again, a plurality of soldering balls 570, 572 disposed between the pads 580, 582 of the side IC 58 and the exposed ends of the TSVs 540, 542 of the active component 54. A plurality of soldering balls 574, 576 disposed at conductive contact 62, 64 of the PCB 60.

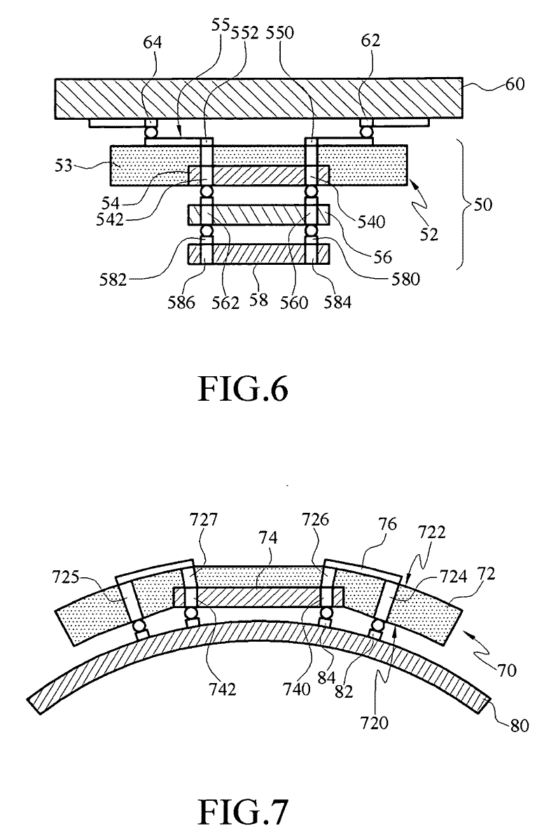

Next, please refer to FIG. 6 which is a schematic cross-sectional view of another embodiment of a 3D chip-stack package according to the invention.

The 3D chip-stack package 50 is adapted to be disposed on a PCB 60 which is the same as the PCB in FIG. 4. The 3D chip-stack package 50 comprises a component-embedded plate 52, a sandwiched IC 56 and a side IC 58.

The sandwiched IC 56 has a plurality of TSVs 560, 562. The sandwiched IC 56 is sandwiched between the active component 54 and the side IC 58 so that the pads 580, 582 of the side IC 58 are electrically connected with the exposed ends of the TSVs 540, 542 of the active component 54 through the TSVs 560, 562 of the sandwiched IC 56.

In this embodiment, there is only one sandwiched IC 56 in the 3D chip-stack package 50. However, in practical application, it is possible to have more than one sandwiched IC 56 in the 3D chip-stack package for limited space consideration.

The active component 54, sandwiched IC 56 and the side IC 58 have integrated electrical circuits inside for performing specific functions. In addition, the side IC 58 in this embodiment is an IC with TSVs 584, 586. The side IC 58 has a plurality of TSVs 584, 586. The TSVs 584, 586 are corresponding to and electrically connected with the conductive pads 580, 582.

The materials of both the dielectric layer 52 and the PCB 60 are organic. For example, the PCB 60 can be, but not limited to, FR-4 (Flame Retardant Type 4) epoxy laminate or polyimide. The dielectric layer 52 can be polymer layer. Therefore, coefficients of thermo expansion (C_{T}) of both the dielectric layer 52 and the PCB 60 are close. Accordingly, thermo stress between the dielectric layer 52 and PCB 60 is reduced.

In addition, please refer to FIG. 7 which is a schematic cross-sectional view of a structure of active component on a substrate according to the invention.

The structure of active component on a substrate comprises a component-embedded plate 70 and a flexible substrate 80.

The component-embedded plate 70 comprises a dielectric layer 72, an active component 74 and an electrical circuit 76. The dielectric layer 72 has a first surface 720, a second surface 722 and a plurality of conductive holes 724, 725, 726, 727. The conductive holes 724, 725, 726, 727 penetrate the dielectric layer 72 and connected between the first surface 720 and the second surface 722.

The active component 74 is embedded in the dielectric layer 72. One surface of active component 74 is exposed outside the first surface 720 of the dielectric layer 72. The active component 74 has a plurality of TSVs 740, 742. One ends of the TSVs 740, 742 are exposed outside the exposed surface of the active component 74. The other ends of the TSVs 740, 742 are connected with a part of the conductive holes 726, 727.

The electrical circuit 76 is on the dielectric layer 72 and in electrical connection between the other ends of the TSVs 740, 742 of the active component 74 and the other part of the conductive holes 724, 725 through the part of the conductive holes 726, 727.

The flexible substrate 80 has a plurality of conductive contacts 82, 84 corresponding to and electrically connected with both the exposed ends of the TSVs 740, 742 and the other part of the through holes 724, 725. The flexible substrate 80 is made of polymer. The polymer is FR-4 (Flame Retardant Type 4) epoxy laminate or polyimide. The dielectric layer 72 is a polymer layer.

The flexible substrate 80 can a heat-dissipating substrate for dissipating heat generated by the active component 74 as well as conducted from conductive holes 724, 725, 726, 727.

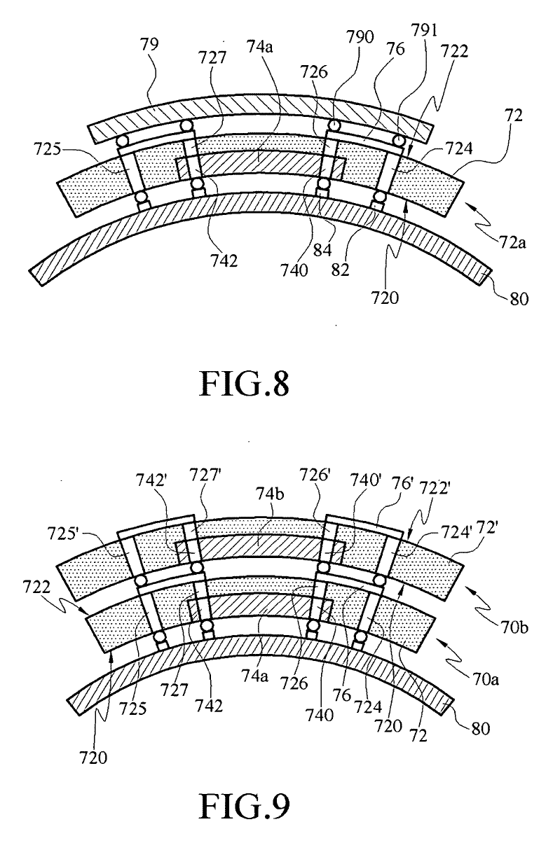

Further, please refer to FIG. 8 which a schematic cross-sectional view of a second embodiment of active component on a substrate according to the invention. The structure of active component on a substrate is similar to that in FIG. 7 and comprises a component-embedded plate 70a and a flexible substrate 80. The same elements will not be described again. The differences includes the active component 74a embedded in the dielectric layer 72 is made by a flexible material. The flexible material can be, but not limited to, polymer.

The component-embedded plate 70a is further stacked by a side IC 79. The side IC 79 has a plurality of conductive pads 790, 791. The pads 790, 791 are electrically connected with the electrical circuit 76. The active component 74a and the side IC 79 have integrated electrical circuits inside for performing specific functions. In addition, the side IC 59 can be a regular IC or an IC with TSVs.

The side IC 79 can be, but not limited to, made by a flexible material. Accordingly, the component-embedded plate 70a and the side IC 79 is bendable and flexible for flexible electronics.

Furthermore, please refer to FIG. 9 which is a schematic cross-sectional view of a third embodiment of active component on a substrate according to the invention. The third embodiment of active component on a substrate comprises a first component-embedded plate 70a, a second component-embedded plate 70b and a flexible substrate 80. The flexible substrate 80 in FIG. 9 is the same as the flexible substrate 80 in FIG. 8. The first and second component-embedded plate 70a, 70b have the same structure as that of the component-embedded plate 70a in FIG. 8. The second component-embedded plate 70b is disposed on the first component-embedded plate 70a.

The second component-embedded plate 70b comprises a dielectric layer 73′, an active component 74b and an electrical circuit 76′. The dielectric layer 72′ has a first surface 720′, a second surface 722′ and a plurality of conductive holes 724′, 725′, 726′, 727′. The conductive holes 724′, 725′, 726′, 727′ penetrate the dielectric layer 72′ and connected between the first surface 720′ and the second surface 722′.

The active component 74b is embedded in the dielectric layer 72′. One surface of active component 74b is exposed outside the first surface 720′ of the dielectric layer 72′. The active component 74b has a plurality of TSVs 740′, 742′. One ends of the TSVs 740′, 742′ are exposed outside the exposed surface of the active component 74b. The other ends of the TSVs 740′, 742′ are connected with a part of the conductive holes 726′, 727′.

The electrical circuit 76′ is on the dielectric layer 72′ and in electrical connection between the other ends of the TSVs 740′, 742′ of the active component 74b and the other part of the conductive holes 724′, 725′ through the part of the conductive holes 726′, 727′.

The second component-embedded plate 70b is disposed upon and electrically connected with the first component-embedded plate 70a. The exposed TSVs 740′, 742′ and the other part of the conductive holes 724′, 725′ of the second component-embedded plate 70b are in electrical connection with the electrical circuit 76 of the first component-embedded plate 70a. Therefore, the active components 74a, 74a are electrically connected for performing some specific functions.

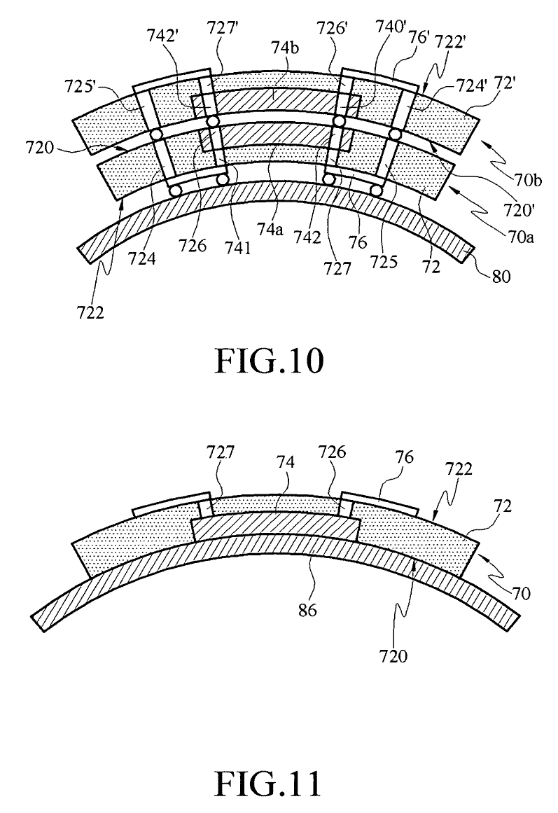

Additionally, please refer to FIG. 10 which is a schematic cross-sectional view of a fourth embodiment of active component on a substrate according to the invention. The fourth embodiment of active component on a substrate comprises a first component-embedded plate 70a, a second component-embedded plate 70a and a flexible substrate 80. The first and second component-embedded plate 70a, 70b have the same structure as that in FIG. 9. Contrast to FIG. 9, the second component-embedded plate 70b is disposed on the first component-embedded plate 70a in face to face manner. In other words, the exposed surface of the active component 74a of the first component-embedded plate 70a faces the exposed surface of the active component 74b of the second component-embedded plate 70b. The TSVs 740, 742 of the first component-embedded plate 70a are in electrical connection with the TSVs 742′, 740′ of the second component-embedded plate 70b, respectively. The conductive holes 724, 725 of the first component-embedded plate 70a are electrically connected with the conductive holes 725′, 724′ of the second component-embedded plate 70b, respectively.

Moving right along, please refer to FIG. 11 which is a schematic cross-sectional view of a fifth embodiment of active component on a substrate according to the invention. According to this embodiment, the active component on a substrate comprises a component-embedded plate 70 and a heat-dissipating substrate 86.

The component-embedded plate 70 comprises a dielectric layer 72, an active component 74 and an electrical circuit 76. The dielectric layer 72 has a first surface 720, a second surface 722 and a plurality of conductive holes 726, 727. The conductive holes 726, 727 penetrate the dielectric layer 72 and connected between the second surface 722 and the active component 74. The active component 74, dielectric layer 72 and the heat-dissipating substrate 86 are bendable and flexible for flexible electronics. The heat-dissipating substrate 86 is contact with both the exposed surface of the active component 74 and the first surface 720 for dissipating heat generated by the active component 74. The heat-dissipating substrate 86 can be, but not limited to, a metal foil or a flexible heat sink. The active component 74 is a thinned (or laminated) and flexible active component. According to said another embodiment of active component on a substrate, heat generated by the active component 74 can be effectively dissipated owing to the contact between the heat-dissipating substrate 86 and the active component 74.

Certain variations would be apparent to those skilled in the art, which variations are considered within the spirit and scope of the claimed invention.

What is claimed is:

1. A three-dimensional (3D) chip-stack package, adapted to be disposed on a printed circuit board (PCB) having a plurality of conductive contacts, the 3D chip-stack package comprising:
a component-embedded plate, comprising
a dielectric layer;
an active component embedded in the dielectric layer, one surface of active component exposed outside the dielectric layer, the active component having a plurality of TSVs (Through Silicon Via), one ends of the TSVs exposed outside the exposed surface of the active component, the other ends of the TSVs corresponding to the conductive contacts of the PCB; and
an electrical circuit on the dielectric layer and in electrical connection between the other ends of the TSVs of the active component and the corresponding conductive contacts of the PCB, respectively; and
a side IC (integrated circuit) having a plurality of pads, the pads electrically connected with the exposed ends of the TSVs of the active component.

2. The 3D chip-stack package of claim 1, further comprising a sandwiched IC, the sandwiched IC having a plurality of TSVs, the sandwiched IC being sandwiched between the active component and the side IC so that the pads of the side IC are electrically connected with the exposed ends of the TSVs of the active component through the TSVs of the sandwiched IC.

3. The 3D chip-stack package of claim 1, wherein the pitches between the TSVs of the active component are smaller than the pitches between the conductive contacts of the PCB.

4. The 3D chip-stack package of claim 1, further comprising a plurality of soldering balls disposed between the pads of the side IC and the exposed ends of the TSVs of the active component.

5. The 3D chip-stack package of claim 1, wherein the side IC has a plurality of TSVs corresponding to and electrically connected with the conductive pads.

6. The 3D chip-stack package of claim 1, wherein the dielectric layer is a polymer layer.

7. The 3D chip-stack package of claim 1, wherein the dielectric layer has a plurality of holes for the electrical circuit to electrically connect to the active components.

8. The 3D chip-stack package of claim 1, further comprising a plurality of soldering balls disposed at conductive contact of the PCB.

9. A structure of active component on a substrate, comprising:
a component-embedded plate, comprising
a dielectric layer having a first surface, a second surface and a plurality of conductive holes, the conductive holes penetrating the dielectric layer and connected between the first surface and the second surface;
an active component embedded in the dielectric layer, one surface of the active component exposed outside the first surface of the dielectric layer, the active component having a plurality of TSVs (Through Silicon Via), one ends of the TSVs exposed outside the exposed surface of the active component, the other ends of the TSVs connected with a part of the conductive holes; and
an electrical circuit on the dielectric layer and in electrical connection between the other ends of the TSVs of the active component and the other part of the conductive holes through the part of the conductive holes; and
a flexible substrate, having a plurality of conductive contacts corresponding to and electrically connected with both the exposed ends of the TSVs and the other part of the through holes.

10. The structure of active component on a substrate of claim 9, wherein the flexible substrate is made of polymer.

11. The structure of active component on a substrate of claim 10, wherein the polymer is FR-4 (Flame Retardant Type 4) epoxy laminate or polyimide.

12. The structure of active component on a substrate of claim 10, wherein the dielectric layer is a polymer layer.

13. The structure of active component on a substrate of claim 10, wherein the flexible substrate is a heat-dissipating substrate.

14. The structure of active component on a substrate of claim 9, further comprising:
an another component-embedded plate, disposed on the second surface of the component-embedded plate, the another component-embedded plate comprising
an another dielectric layer having an another first surface, an another second surface and a plurality of another conductive holes, the another conductive holes penetrating the another dielectric layer and connected between the another first surface and the another second surface;
an another active component embedded in the another dielectric layer, one surface of the another active component exposed outside the another first surface of the another dielectric layer, the another active component having a plurality of another TSVs (Through Silicon Via), one ends of the another TSVs exposed outside the exposed surface of the another active component, the other ends of the another TSVs connected with a part of the another conductive holes; and
an another electrical circuit on the another dielectric layer and in electrical connection between the other ends of the another TSVs of the another active component and the other part of the another conductive holes through the part of the another conductive holes, the ends of the another TSVs and the part of the another conductive holes being electrically connected with the electrical circuit of the component-embedded plate.

15. The structure of active component on a substrate of claim 9, further comprising:
a side IC (integrated circuit) having a plurality of pads, the pads electrically connected with the electrical circuit.

16. The structure of active component on a substrate of claim 9, further comprising:
an another component-embedded plate, interposed between the component-embedded plate and the flexible substrate, the another component-embedded plate comprising
an another dielectric layer having an another first surface, an another second surface and a plurality of another conductive holes, the another conductive holes penetrating the another dielectric layer and connected between the another first surface and the another second surface;
an another active component embedded in the another dielectric layer, one surface of the another active component exposed outside the another first surface of the another dielectric layer, the exposed surface of the another active component facing the exposed surface of the active component, the another active component having a plurality of another TSVs (Through Silicon Via), one ends of the another TSVs exposed outside the exposed surface of the another active component, the other ends of the another TSVs connected with a part of the another conductive holes; and
an another electrical circuit on the another dielectric layer and in electrical connection between the other ends of the another TSVs of the another active component and the other part of the another conductive holes through the part of the another conductive holes, the another electrical circuit being electrically connected between the electrical circuit of the component-embedded plate and the conductive contacts of the flexible substrate.

17. A structure of active component on a substrate, comprising:
a component-embedded plate, comprising
a dielectric layer having a first surface, a second surface and a plurality of conductive holes, the conductive holes penetrating the dielectric layer and connected between the first surface and the second surface;
an active component embedded in the dielectric layer, one surface of the active component exposed outside the first surface of the dielectric layer; and
an electrical circuit on the dielectric layer and in electrical connection between the active component through the conductive holes; and
a heat-dissipating substrate, being contact with the exposed surface of the active component and the first surface of the dialectical layer.
